(19) United States
(12) Patent Application Publication
(10) Pub. No.: US 2026/0362676 A1
(43) Pub. Date: Nov. 12, 2026

(54) APPARATUS INCLUDING CELL CONTACT AND REDISTRIBUTION LAYER STRUCTURE

(71) Applicant: Micron Technology, Inc., Boise, ID (US)

(72) Inventors: CHONG ZAN WU, Taichung (TW); Albert P. Chan, Boise, ID (US); Manabu Ito, Higashihiroshima-shi (JP)

(73) Assignee: Micron Technology, Inc., Boise, ID (US)

(21) Appl. No.: 19/649,508

(22) Filed: Apr. 16, 2026

Related U.S. Application Data
(60) Provisional application No. 63/802,322, filed on May 8, 2025.

(51) Int. Cl. H10B 12/00

(52) U.S. Cl. CPC H10B 12/315; H10B 12/0335

(57) ABSTRACT

Embodiments of the disclosure provide an apparatus comprising a cell contact, a redistribution layer (RDL), and a memory cell capacitor on a semiconductor substrate. The cell contact is coupled to the cell capacitor via the RDL. The cell contact is coupled to a source/drain region in the semiconductor substrate. The cell capacitor is coupled to the source/drain region via the cell contact and the RDL. The cell contact includes a contact metal and a barrier metal, and may include a barrier metal recess having a top part of the barrier metal lower than a top part of the contact metal. The barrier metal recess provides a gap between the barrier metal of the cell contact and that of the neighboring cell contact to prevent a barrier metal-barrier metal short circuit. The barrier metal recess may also provide a gap from the neighboring RDL to prevent a barrier metal-RDL short circuit.

### CROSS REFERENCE TO RELATED APPLICATIONS

This application claims the benefit under 35 U.S.C. § 119 of the earlier filing date of U.S. Provisional Application Serial No. 63/802,322 filed May 8, 2025. The aforementioned application is incorporated herein by reference, in its entirety, for any purpose.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines arranged in rows and bit lines arranged in columns in a memory cell array. Each memory cell may include a capacitor for data storage and a transistor for accessing the capacitor. A memory cell capacitor may be coupled to either source or drain of an associated memory cell transistor formed in active regions of a semiconductor substrate, via a cell contact and a redistribution layer. A cell contact may be coupled at one end to either the source or drain region and at another end to a redistribution layer. The redistribution layer may then be coupled to the associated memory cell capacitor. The cell contact and the redistribution layer may thus serve to couple the cell capacitor to one of the source/drain regions in the semiconductor substrate. A bit line may be coupled to the other source/drain region.

### BRIEF DESCRIPTION OF THE DRAWINGS

FIGS. 1A and 1B depict an example configuration of at least part of a memory device in a plan view and a cross-sectional view, respectively, according to some embodiments of the disclosure.

FIGS. 2A-2B-7A-7B depict example processes of forming at least part of a memory device in a plan view and a cross-sectional view according to some embodiments of the disclosure.

FIG. 8 depicts an example configuration of at least part of a memory device in a cross-sectional view according to some embodiments of the disclosure.

FIG. 9 depicts a schematic configuration of an example semiconductor system according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

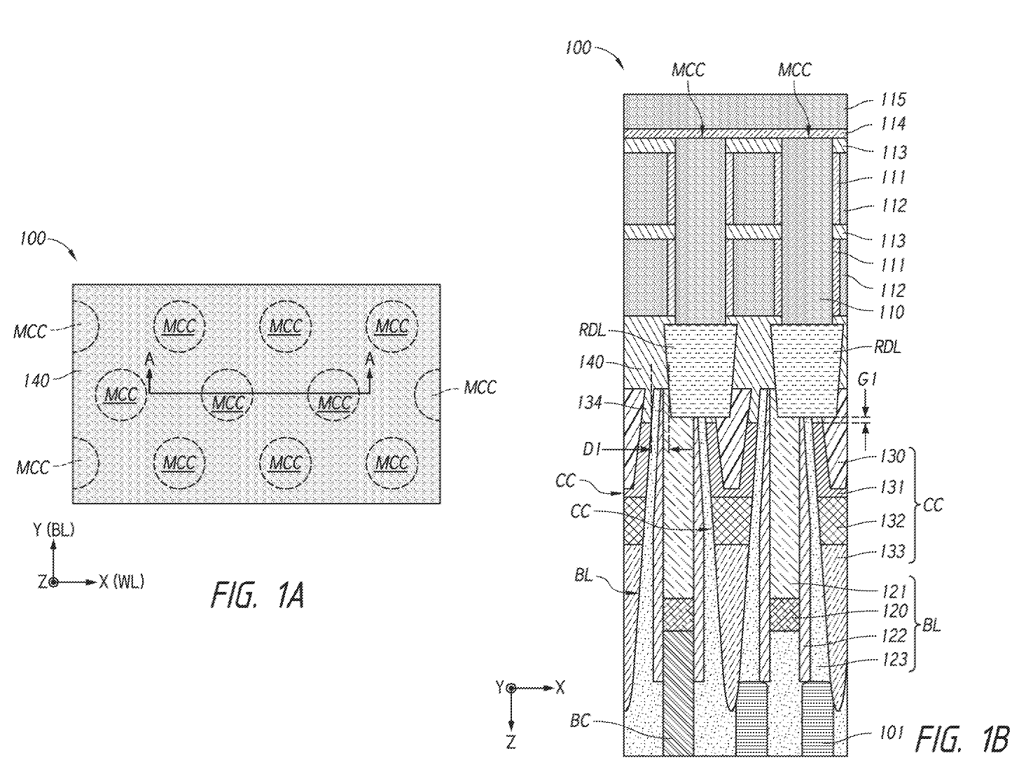

FIGS. 1A and 1B depict an example configuration of at least part of a memory device 100 in a plan view and a cross-sectional view, respectively, according to some embodiments of the disclosure. The cross-sectional view of FIG. 1B corresponds to line A-A in FIG. 1A. The size, position, and other aspects of the cross-sectional view may not necessarily match those of the plan view in the drawings. The memory device 100 may be a dynamic random-access memory (DRAM). The memory device 100 may be one example of a semiconductor device. The memory device 100 may be one example of an apparatus. The memory device 100 may include a memory cell array region and a peripheral region on a semiconductor substrate 101, such as a silicon substrate. The memory cell array region may include a plurality of memory cells arranged at intersections of word lines and bit lines. The memory cell array region may have a square shape, a rectangular shape, or the like in a plan view on the semiconductor substrate 101. The peripheral region may be provided adjacent to the memory cell array region. The peripheral region may be provided around the memory cell array region in the plan view on the semiconductor substrate.

The memory device 100 includes a plurality of memory cell capacitors MCC at least in a memory cell array region. The memory cell capacitors MCC each may include a conductive pillar 110. The conductive pillar 110 may serve as a lower (or bottom) capacitor electrode and may include a conductive material, such as a metal (e.g., titanium nitride (TiN)). The memory cell capacitors MCC each may further include a dielectric layer 111 and a conductive layer 112. The conductive layer 112 may serve as an upper (or top) capacitor electrode and may include the same material as the lower electrode, such as TiN. The dielectric layer 111 is sandwiched between the lower and upper electrodes and may include an insulating material, such as a high-k dielectric material (e.g., Zirconium Oxide (ZrO₂) and hafnium oxide (HfO₂)). The memory cell capacitors MCC may be pillar-type capacitors. The depicted example configuration may further include insulating layers 113. The insulating layers 113 may include an insulating material, such as silicon nitride (Si₃N₄ or simply SiN). Another high-k layer 114 and another conductive layer 115 may also be provided on the memory cell capacitors MCC and neighboring structures. In some instances, additional insulating layers and/or conductive layers may be provided as appropriate. The memory cell capacitors MCC may be arranged at intersections of word lines (not separately depicted) and bit lines BL. The memory cell capacitors MCC may be arranged in matrix. Each memory cell capacitor MCC may form at least part of a memory cell to store data by accumulating electric charges therein and to be accessed via the associated word line and bit line during data write and read operations. Each memory cell capacitor MCC may include a vertical capacitor structure that extends in a vertical direction, which may be for example a Z-axis direction in the drawing. Bit lines BL (may also be referred to as digit lines or data lines) may be arranged in parallel with each other in a first horizontal direction, which may be for example an X-axis direction in the drawing, and each may extend in a second horizontal direction, which may be for example a Y-axis direction in the drawing, orthogonal (or substantially orthogonal within reasonable tolerances of fabrication, measurement, etc.) to the first horizontal direction. Word lines may be arranged in parallel with each other in the Y-axis direction and each may extend in the X-axis direction, intersecting with bit lines BL in the plan view (for example, in a plane along the X-axis direction and the Y-axis direction). The X-axis direction and the Y-axis direction may also be referred to as a word line (WL) direction and a bit line (BL) direction, respectively.

Each bit line BL includes a bit line structure, which includes at least a conductive part 120. The conductive part 120 may include a conductive material, such as a metal (e.g., tungsten (W)). The conductive part 120 may also be referred to as a bit line metal. On the conductive part 120 is an insulating layer 121 including an insulating material, such as SiN. The insulating layer 121 may serve as a mask layer or a cap layer. Furthermore, an insulating film 122 may be provided on side surfaces of the conductive part 120 and the insulating layer 121. The insulating film 122 may include an insulating material, such as silicon oxide (SiO₂ or simply SiO). Still furthermore, another insulating film 123 may be provided on the insulating film 122. The insulating film 123 may include an insulating material, such as SiN, different from the insulating material of the insulating film 122. The insulating films 122 and 123 may also be part of the bit line structure. The insulating films 122 and 123 may be insulating spacers. The insulating films 122 and 123 may provide a sidewall of the bit line structure. In some instances, other elements, films, layers, or the like may be included in the bit line structure. The bit lines BL may be coupled to active regions (one of source/drain regions of a memory cell access transistor, for example) formed in the semiconductor substrate 101 via bit line contacts BC. Each bit line contact BC may include a conductive material, such as polycrystalline silicon or polysilicon (poly-Si), for example.

The memory device 100 includes cell contacts CC and redistribution layers RDL arranged in matrix corresponding to the matrix of the memory cell capacitors MCC. The cell contacts CC have lower portions coupled to other active regions (another of the source/drain regions of the access transistor, for example) of the semiconductor substrate 101. The redistribution layers RDL have lower portions and upper portions coupled to the associated cell contacts CC and the associated memory cell capacitors MCC, respectively. The cell contacts CC and the redistributions layer RDL couple the associated memory cell capacitors MCC to the active regions of the semiconductor substrate 101. The redistribution layers RDL are arranged to contact at least upper portions of the cell contacts CC. The redistribution layers RDL may also contact upper portions of the bit lines BL adjacent to the cell contacts CC. The redistribution layers RDL may include a conductive material, such as W.

Each cell contact CC includes a cell contact structure, which includes at least a first contact part 130 and a second contact part 131. The first contact part 130 extends in the Z-axis direction and may include a conductive material, such as a metal (e.g., W). The second contact part 131 is provided at least on a side surface of the first contact part 130. The second contact part 131 may also be provided on a bottom surface of the first contact part 130. The second contact part 131 may include a conductive material, such as a metal (e.g., titanium (T) and TiN), different from the conductive material of the first contact part 130. The conductive material of the second contact part 131 may serve as a barrier metal. The barrier metal may be provided in a film form on the side and bottom surfaces of the first contact part 130. The first contact part 130 and the second contact part 131 may also be referred to as a contact metal and a barrier metal (or a barrier metal film), respectively, of the cell contact CC. In some instances, the second contact part 131 as the barrier metal may be formed in a contact hole (not separately depicted in FIGS. 1A and 1B), and the first contact part 130 as the contact metal may be formed on the second contact part 131 filling the contact hole. In the depicted example configuration, under the first and second contact parts 130 and 131 are a third contact part 132 and a fourth contact part 133. The third contact part 132 may include cobalt (Co) or cobalt silicide (CoSi₂) between the second and fourth contact parts 132 and 133. The third contact part 132 may also be referred to as a contact cobalt. The fourth contact part 133 extends into the semiconductor substrate 101 in the Z-axis direction, and may include poly-Si. The fourth contact part 133 may also be referred to as a contact poly. The fourth contact part 133 at a lower end thereof is coupled to the active region formed in the semiconductor substrate 101. The third and fourth contact parts 132 and 133 may also be part of the cell contact structure. The first and second contact parts 130 and 131 are coupled to the active regions of the semiconductor substrate 101 via the third and fourth contact parts 132 and 133. In some instances, other elements, films, layers, or the like may be included in the cell contact structure.

In the depicted example configuration, a top portion of the second contact part (hereinafter referred to as the barrier metal) 131 is lower than a top portion of the first contact part (hereinafter referred to as the contact metal) 130. This provides a recess 134 of the barrier metal 131 between an upper portion of the contact metal 130 and the sidewall of the neighboring bit line/bit line structure BL. In the depicted example, the sidewall of the bit line structure is slanted, and the upper portion of the contact metal 130 has a slanted side surface in parallel to the slanted sidewall of the

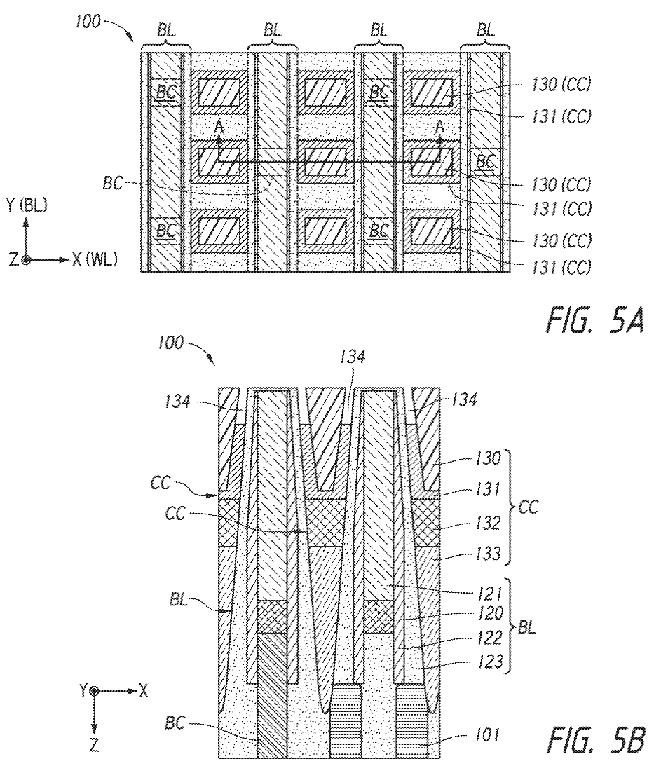

bit line structure. The barrier metal recess 134 formed between the upper portion of the contact metal 130 and the sidewall of the bit line structure thus has a slanted shape. The barrier metal recess 134 (also see 134 in FIG. 5B, for example) is filled with an insulating material, such as SiN. The insulating material may be part of an insulating layer 140 that covers the top portion of each cell contact CC. The insulating layer 140 also covers top parts of the bit lines BL and fills spaces between neighboring redistribution layers RDL. In some instances, the barrier metal 131 (such as Ti and TiN) and the contact metal 130 (such as W) may be first provided in the contact hole formed between the bit lines BL and then polished by for example chemical-mechanical polishing (CMP) to reveal the top parts of the bit lines BL and to separate the neighboring contact cells CC from each other. This is followed by the formation of an insulating layer, including an insulating material (such as nitride), to cover the polished parts. However, there may be a case where the barrier metal 131 is not sufficiently polished, leaving some portions remaining on the top parts of the big lines BL. This may result in barrier metal short between neighboring contact cells CC. For instance, to achieve a lower aspect ratio in the array regio, the height of the insulating (nitride) layer may be reduced to induce array-periphery height marginality. This, in turn, stresses metal CMP capability to control the over-polish amount so as not to over polish the contact metal 130 and the barrier metal 131. This, on the other hand, may lead to under-polishing of the metal, especially the barrier metal 131, causing the formation of a conductive bridge that connects the neighboring contact cells CC. As a measure to address the under-polish issue and to prevent barrier metal shorting, in some instances, after the metal polishing process, the barrier metal 131 may be selectively wet-etched to remove and lower the top part thereof below the top part of the contact metal 130. The insulating material (such as nitride) is subsequently deposited to fill the barrier metal recess 134 created by the wet etching of the barrier metal 131. The redistribution layers RDL formed thereafter couple only to their associated cell contacts. As illustrated in FIG. 1B, since the top part of the barrier metal 131 is lowered and the recess 134 is provided, the redistribution layer RDL and the barrier metal 131 of the neighboring contact cell CC, other than the associated contact cell CC, maintain a sufficient distance D1 or sufficiently increase the distance D1 to prevent electrical coupling. Therefore, in the present embodiments, the top part of the barrier metal 131 is sufficiently lower than the top part of the contact metal 130 to prevent both barrier metal-to-barrier metal shorting and barrier metal-to-redistribution layer shorting.

In the depicted example configuration, the top part of the barrier metal 131 is also lower than a bottom part of the associated redistribution layer RDL (see gap G1 in FIG. 1B). In other instances, the top portion of the barrier metal 131 may touch the bottom portion of the associated redistribution layer RDL with no gap.

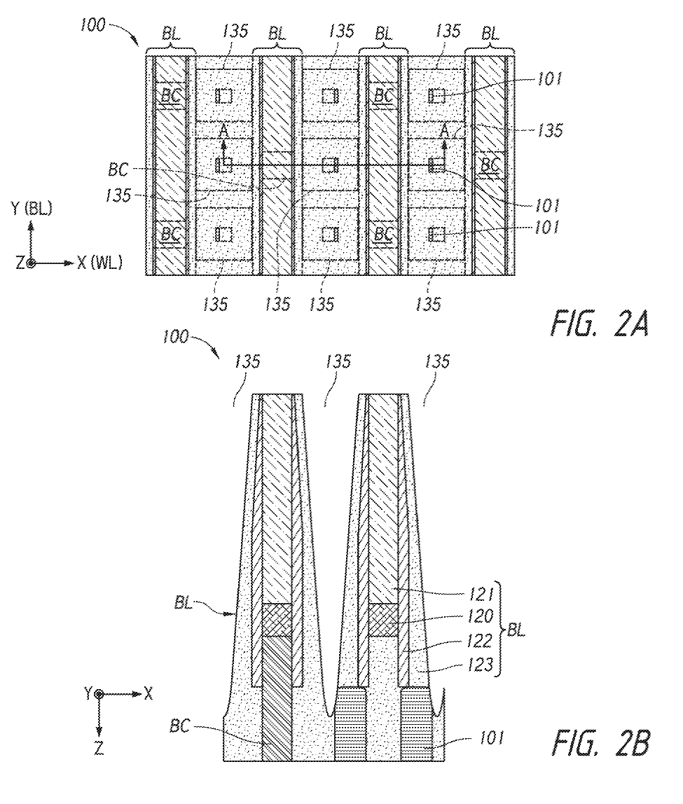

FIGS. 2A-2B-7A-7B to depict example processes of forming at least part of the memory device 100 including the cell contacts CC and the redistribution layers RDL in a plan view and a cross-sectional view according to some embodiments of the disclosure. FIGS. 2A-6A depict the processes in the plan view. The cross-sectional views in FIGS. 2B-6B correspond to line A-A in FIGS. 2A-6A. The size, position, and other aspects of the cross-sectional views may not necessarily match those of the plan views in the drawings. The memory device 100 of these figures corresponds to the memory device 100 of FIGS. 1A-1B. An example method to form at least part of a memory device according to some embodiments of the disclosure may include the processes described below.

First, as shown in FIGS. 2A and 2B, a part of the memory device 100 is formed, including, for example, the bit line contacts BC in the semiconductor substrate 101 and the bit lines/bit line structures BL (hereinafter referred to as bit line structures BL) on the semiconductor substrate 101. Between the neighboring bit line structures BL are cell contact holes 135 each patterned to vertically extend into the semiconductor substrate 101. The cell contact holes 135 may be formed by conventional methods, such as photolithography and etching, as appropriate.

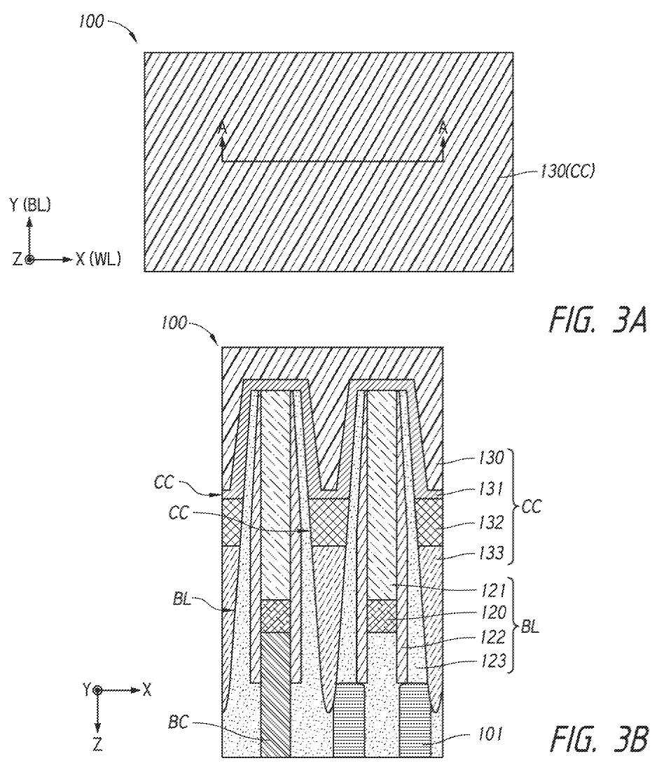

Next, as shown in FIGS. 3A and 3B, the cell contacts CC are formed in the respective cell contact holes 135. The fourth contact part (contact poly) 133 and the third contact part (contact cobalt) 132 of the cell contact structure are first formed by depositing poly-Si and Co or CoSi₂ to the lower portion of the cell contact hole 135. Conventional deposition methods may be used as appropriate. More specifically, as one example, the material (poly-Si) of the fourth contact part 133 may be deposited, and a portion of the fourth contact part 133 may be removed by dry etching so that a remaining portion of the fourth contact part 133 is buried in the cell contact hole 135, followed by deposition of the material (Co or CoSi₂) of the third contact part 132 on the fourth contact part 133 in the cell contact hole 135. Subsequently, the second contact part (barrier metal) 131 and the first contact part (contact metal) 130 of the cell contact structure are provided on the third contact part 132 in the upper portion of the cell contact hole 135. More specifically, as one example, the barrier metal 131 (such as Ti or TiN) is first provided in a film shape on a top surface of the third contact part 132 and a side surface of the cell contact hole 135 as well as on a top portion of the bit line structure BL. The contact metal 130 (such as W) is then provided on the barrier metal 131 and the top portion of the bit line structure BL. The contact metal 130 covers the barrier metal 131 and fills the cell contact hole 135. The formation of the cell contact structure may be performed by any conventional methods including deposition and etching as appropriate.

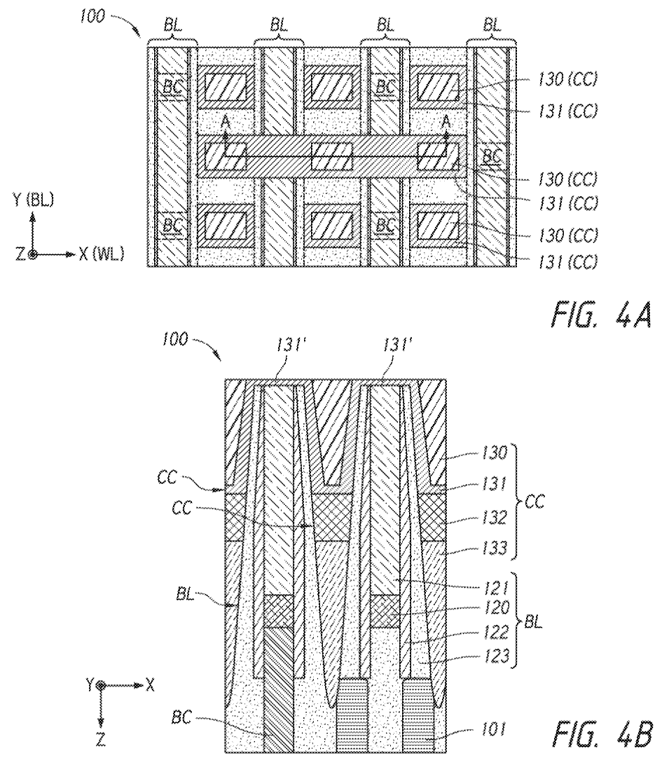

Next, as shown in FIGS. 4A and 4B, a portion of the barrier metal 131 on the top portion of the bit line structure BL and the contact metal 130 above the bit line structure BL are removed by, for example, chemical-mechanical polishing CMP. In some instances, however, the portion 131’ of the barrier metal 131 may be left on the top portion of the bit line structure BL due to under-polishing. This portion 131’ may form a conductive bridge between the neighboring cell contact structures CC and may cause a short circuit.

To effectively avoid such a short circuit, as shown in FIGS. 5A and 5B, the portion 131’ and an additional portion of the barrier metal 131 are selectively removed by, for example, wet etching. In the present embodiments, the selective wet etching may use an etchant with greater selectivity for the barrier metal 131 (such as Ti and TiN) than for the contact metal 130 (such as W). Additionally, the etchant may exhibit higher selectivity for the barrier metal 131 than for the bit line structure BL (such as SiN and SiO). As one example, the wet etchant may include sulfuric acid (H₂SO₄) exhibiting such selectivity.

Other wet etch conditions, such as wet etch process time and/or wet etch temperature, may also be appropriately determined such that the top part of the barrier metal 131 is sufficiently lowered to secure the distance D1 (see FIG. 1B) from the redistribution layer RDL which is to be formed at a later process. By adjusting the conditions of the wet etching including etchant, etch time, temperature, and the like, the top part of the barrier metal 131 is selectively etched to be lower than the top part of the contact metal 130. This removal of the top part of the barrier metal 131 forms the recess 134 between the lowered top part of the barrier metal 131 and the top part of the contact metal 130. Adjusting the wet etching conditions can determine how deep the recess 134 is formed. The barrier metal recess 134 is located between the side surface of the contact metal 130 and the sidewall of the bit line structure BL. The barrier metal recess 134 provides a gap between the barrier metals 131 of the neighboring cell contacts CC. This way, the neighboring cell contacts CC are fully separated from each other and a barrier metal short circuit is effectively prevented.

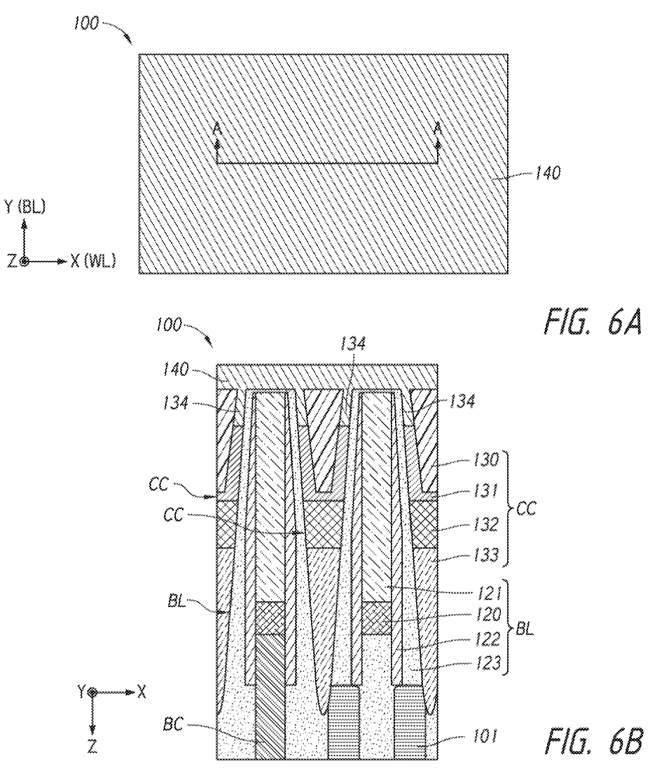

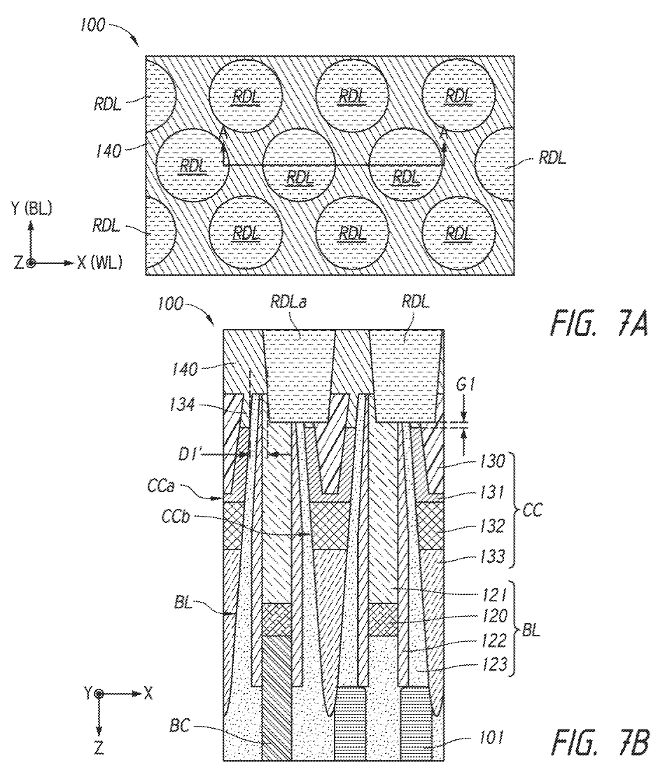

Subsequently, as shown in FIGS. 6A and 6B, the insulating layer 140 is provided on the cell contact structures CC and the bit line structures BL, and as shown in FIGS. 7A and 7B, the redistribution layers RDL are formed. Conventional methods, such as deposition, photolithography and etching, may be used as appropriate. The insulating material (such as SiN) of the insulating layer 140 fills the barrier metal recess 134. The redistribution layers RDL may be provided by, for example, forming trenches or holes at positions to contact the respective bit lines BL and the contact metals 130 of the respective cell contacts CC and filling the trenches/holes with the conductive material (such as W). In the resultant structure, the barrier metal 131 is sufficiently lower than the contact metal 130 so that, as illustrated, the neighboring cell contacts CCa and CCb are not shorted and the neighboring redistribution layer RDLa and cell contact CCa maintain the distance D1 to avoid electrical coupling and prevent a barrier metal-to-RDL short circuit. Furthermore, the associated redistribution layer RDLa and cell contact CCa coupled to each other has the gap G1 between the lowered top surface of the barrier metal 131 and the facing bottom surface of the redistribution layer RDL.

Following the above process, as shown in FIGS. 1A and 1B, the memory cell capacitors MCC are formed on the corresponding redistribution layers RDL. Accordingly, the present embodiments can realize the memory device 100 that can effectively prevent or mitigate occurrence of various shorting.

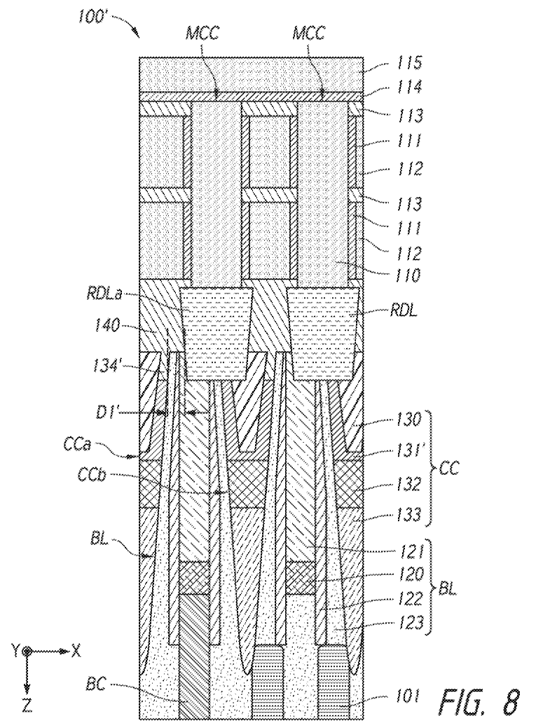

FIG. 8 depicts an example configuration of at least part of a memory device 100’ according to some embodiments of the disclosure. The memory device 100’ of FIG. 8 corresponds to the memory device 100 of the above described figures, except that: while FIG. 7B shows the case where the cell contact CCband the redistribution layer RDLa coupled to each other has the gap G1, the configuration of FIG. 8 does not have the gap between the coupled cell contact CCb and redistribution layer RDLa. This is possible by adjusting the wet etching conditions of the barrier metal 131’ to control the depth of the recess 134’. The top surface of the barrier metal 131’ of the cell contact CCb and the bottom surface of the redistribution layer RDLa thus contact with each other. Still, the neighboring cell contact CCa and redistribution layer RDLa are isolated from each other so as not to be electrically coupled. In this configuration, distance D1’ may be slightly shorter than D1 in the configuration of FIG. 7B (or FIG. 1B) because the top surface of the barrier metal 131’ may be slightly closer to the redistribution layer RDLa due to the shallower depth of the recess 134’ and the slanted side configuration of the cell contact and bit line structure. Still, the neighboring cell contact CCa and redistribution layer RDLa maintains the sufficient distance D1’ to prevent barrier metal-to-RDL shorting.

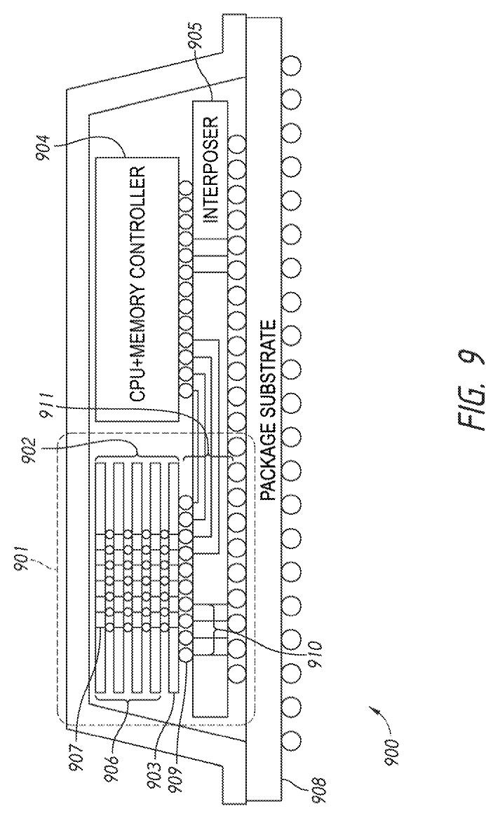

FIG. 9 depicts a schematic configuration of an example semiconductor system 900 according to some embodiments of the disclosure. The semiconductor system 900 includes a semiconductor memory device 901 in an embodiment of the disclosure. In some embodiments of the disclosure, the semiconductor memory device 901 may include the memory device 100 of FIGS. 1A-1B or the memory device 100’ of FIG. 8. The semiconductor system 900 may also include a central processing unit (CPU) and memory controller 904, which may be a controller chip, on an interposer 905 on a package substrate 908. The interposer 905 may include one or more power lines 910 which may supply power supply voltage from the package substrate 908. The interposer 905 may include a plurality of channels 911 that may interconnect the CPU and memory controller 904 and the semiconductor memory device 901. The semiconductor memory device 901 may be a DRAM. The memory controller 904 may provide a clock signal, a command signal, and may further transmit and receive data signals. The plurality of channels 911 may transmit the data signals between the memory controller and the memory device 901.

The semiconductor memory device 901 may include a plurality of dies (or chips) 902 including at least one interface (IF) die (or chip) 903 and a plurality of memory core dies (or chips) 906 stacked with each other. A number of the memory core dies 906 may not be limited to four as in the illustrated example, and may be more or fewer as appropriate. Each of the memory core dies 906 may include a plurality of memory cells and circuitries accessing the memory cells. For example, the memory cells may be DRAM cells. The memory cells may be arranged in array. The semiconductor memory device 901 may include conductive vias 907 which couple the IF die 903 and the memory core dies 906 by penetrating the IF die 903 and the memory core dies 906. The IF die 903 may be coupled to the interposer 905 via interconnects 909. For example, the interconnects 909 may be microbumps having bump pitches of less than about or less than one hundred micrometers and exposed on an outside of the IF die 903. A portion of each of the interconnects 909 may be coupled to the one or more power lines 910. Another portion of each of the interconnects 909 may be coupled to one or more of the channels 911.

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising a cell contact coupled to a memory cell capacitor via a redistribution layer (RDL), the cell contact including a contact metal and a barrier metal at least on a side surface of the contact metal, wherein
the cell contact includes a top part of the barrier metal lower than a top part of the contact metal, and includes a barrier metal recess on the top part of the barrier metal, the barrier metal recess filled with an insulating material.

2. The apparatus according to claim 1, further including a bit line structure adjacent to the cell contact, wherein the cell contact includes the barrier metal recess between a side surface of the contact metal and a sidewall of the bit line structure.

3. The apparatus according to claim 1, wherein the insulating material covers the top part of the contact metal.

4. The apparatus according to claim 1, wherein the insulating material includes silicon nitride.

5. The apparatus according to claim 1, wherein the contact metal includes tungsten, and the barrier metal includes titanium or titanium nitride.

6. The apparatus according to claim 1, comprising a first cell contact and a second cell contact as the cell contact, a bit line structure between the first cell contact and the second cell contact, and the RDL coupled to the second cell contact, wherein
the barrier metal of the first cell contact and the barrier metal of the second cell contact includes a first barrier metal recess and a second barrier metal recess, respectively,
the first barrier metal recess of the first cell contact and the second barrier metal recess of the second cell contact are not coupled to each other, and
the first barrier metal recess of the first cell contact is not coupled to the RDL coupled to the second cell contact.

7. The apparatus according to claim 6, wherein the RDL is coupled to the contact metal of the second cell contact and the adjacent bit line structure.

8. The apparatus according to claim 1, comprising a first cell contact and a second cell contact as the cell contact, and the RDL coupled to the second cell contact, wherein
the first cell contact includes the top part of the barrier metal lowered below the top part of the contact metal to increase a distance between the barrier metal of the first cell contact and the RDL coupled to the second cell contact.

9. The apparatus according to claim 1, comprising a first cell contact and a second cell contact as the cell contact, the first and second cell contacts adjacent to each other, and the RDL provided between the first and second cell contacts and coupled to the second cell contact, wherein
a top part of the barrier metal of the first cell contact is lowered to prevent coupling to the barrier metal of the second cell contact and increase a distance from the RDL coupled to the second cell contact.

10. The apparatus according to claim 1, wherein the top part of the barrier metal is lower than a bottom part of the RDL.

11. The apparatus according to claim 1, wherein the top part of the barrier metal touches a bottom part of the RDL.

12. An apparatus, comprising:
a first cell contact and a second cell contact each coupled to a source/drain region formed in a semiconductor substrate, the first and second cell contacts each including a first contact part and a second contact part on side and bottom surfaces of the first contact part, the first cell contact and the second cell contact adjacent to each other; and
a redistribution layer (RDL) coupled to the second cell contact at one end and a memory cell capacitor at another end, wherein
at least the first cell contact has a top portion of the second contact part lower than a top portion of the first contact part and provides a gap between the second contact part and the RDL coupled to the second cell contact.

13. The apparatus according to claim 12, wherein the gap is provided between the second contact part of the first cell contact and a side surface of the RDL in a horizontal direction.

14. The apparatus according to claim 12, wherein the second cell contact has a top portion of the second contact part lower than a top portion of the first contact part.

15. The apparatus according to claim 14, wherein the second contact part of the first cell contact is not coupled to the second contact part of the second cell contact.

16. The apparatus according to claim 14, wherein the top portion of the second contact part of the second cell contact is lower than a bottom portion of the RDL.

17. The apparatus according to claim 14, wherein the top portion of the second contact part of the second cell contact is coupled to a bottom portion of the RDL.

18. The apparatus according to claim 12, wherein the first contact part includes a contact metal, and the second contact part includes a barrier metal.

19. An apparatus, comprising:
a plurality of cell contacts arranged in matrix, each coupled to an active region of a semiconductor substrate;
a plurality of redistribution layers (RDLs) arranged in matrix above the plurality of cell contacts, each coupled to an associated cell contact of the plurality of cell contacts; and
a plurality of memory cell capacitors arranged in matrix above the plurality of RDLs, each coupled to an associated RDL of the plurality of RDLs, wherein
each of the plurality of cell contacts has a contact metal coupled to the associated RDL and a barrier metal at least on a side surface of the contact metal, and
the barrier metal has a lowered top surface below a top surface of the contact metal.

20. The apparatus according to claim 19, wherein the barrier metal with the lowered top surface is not coupled to a barrier metal of a neighboring cell contact and is not coupled to a neighboring RDL that is coupled to the neighboring cell contact.
